(19) United States
(12) Patent Application Publication
(10) Pub. No.: US 2022/0206051 A1
(43) Pub. Date: Jun. 30, 2022

(54) BROADBAND INTERFEROMETER LIGHTNING POSITIONING METHOD BASED ON PULSE MATCHING AND SYSTEM THEREOF

(71) Applicant: Chinese Academy of Meteorological Sciences, Beijing (CN)

(72) Inventors: Xiangpeng FAN, Beijing (CN); Yijun ZHANG, Beijing (CN); Dong ZHENG, Beijing (CN); Wen YAO, Beijing (CN)

(21) Appl. No.: 17/197,462

(22) Filed: Mar. 10, 2021

(30) Foreign Application Priority Data
Dec. 28, 2020 (CN) 202011574774.7

(51) Int. Cl. G01R 29/08; G01R 29/033; G01S 5/16

(52) U.S. Cl. CPC G01R 29/0842; G01S 5/16; G01R 29/033

(57) ABSTRACT

A broadband interferometer lightning positioning method based on pulse matching and a system thereof that improves the positioning accuracy of the interferometer to the lightning radiation source. The method includes acquiring a very high frequency radiation pulse signal set of lightning; determining a first very high frequency radiation pulse signal within a set time period as a reference pulse signal; determining a first comparison pulse signal, and determining a second comparison pulse signal; moving both the first comparison pulse signal and the second comparison pulse signal to the position corresponding to the reference pulse signal using the cross-correlation algorithm to obtain a pulse signal set, simultaneously covering each pulse signal in the pulse signal set using a sliding window with a set width to determine the position of the lightning radiation source.

### CROSS REFERENCE TO RELATED APPLICATIONS

The present application claims priority under 35 U.S.C. § 119 to Chinese Patent Application No. 202011574774.7 filed (Dec. 28, 2020), which is hereby incorporated by reference in their complete respective entireties.

### TECHNICAL FIELD

The present disclosure relates to the technical field of lightning positioning, in particular to a broadband interferometer lightning positioning method based on pulse matching and a system thereof.

### BACKGROUND

At present, the commonly used interferometer positioning technology usually uses a signal with a certain width as a window and progresses on the synchronous detection signal with a certain step size (a set number of sampling points). This method is usually referred to as a centroid approach. In theory, this method can obtain a locating point each time progressing by a step in theory. Therefore, the theoretical minimum time resolution is the time represented by the progressive step, but this is far from the theoretical value in practice. On the one hand, due to the existence of the window, repeated locating points will be obtained in several progress, because the time difference obtained by the cross-correlation method is actually determined by the strongest pulse in the window, that is to say, there will be many overlapping locating points that are repeatedly positioned; on the other hand, for interferometers operating in a very high frequency (VHF) band, there are usually dozens of pulse signals in the progressive window corresponding to a set number of sampling points, which leads to the weak pulse signals in the window being usually unable to be positioned, resulting in inaccurate lightning positioning.

### SUMMARY

The object of the present disclosure is to provide a broadband interferometer lightning positioning method based on pulse matching and a system thereof, so as to improve the positioning accuracy of the interferometer for the lightning radiation sources.

To achieve the above object, the present disclosure provides the following scheme.

A broadband interferometer lightning positioning method based on pulse matching comprises: acquiring a very high frequency radiation pulse signal set of lightning emitted by a lightning radiation source, wherein the very high frequency radiation pulse signal set comprises a first very high frequency radiation pulse signal, a second very high frequency radiation pulse signal and a third very high frequency radiation pulse signal, and the very high frequency radiation pulse signal set is simultaneously acquired by three antennas forming a broadband very high frequency interferometer; determining the first very high frequency radiation pulse signal within a set time period as a reference pulse signal; determining the pulse signal in the second very high frequency radiation pulse signal whose waveform difference with the reference pulse signal is within a first set range as a first comparison pulse signal, and determining the pulse signal in the third very high frequency radiation pulse signal whose waveform difference with the reference pulse signal is within a second set range as a second comparison pulse signal; moving both the first comparison pulse signal and the second comparison pulse signal to the position corresponding to the reference pulse signal using the cross-correlation algorithm to obtain a pulse signal set, wherein the pulse signal set comprises a matched first comparison pulse signal, a matched second comparison pulse signal and a matched reference pulse signal; and covering each pulse signal in the pulse signal set at the same time using a sliding window with a set width to determine the position of the lightning radiation source.

A broadband interferometer lightning positioning system based on pulse matching comprises: an acquiring module, which is configured to acquire a very high frequency radiation pulse signal set of lightning emitted by a lightning radiation source, wherein the very high frequency radiation pulse signal set comprises a first very high frequency radiation pulse signal, a second very high frequency radiation pulse signal and a third very high frequency radiation pulse signal, and the very high frequency radiation pulse signal set is simultaneously acquired by three antennas forming a broadband very high frequency interferometer; a reference signal determining module, which is configured to determine the first very high frequency radiation pulse signal within a set time period as a reference pulse signal; a comparison signal acquiring module, which is configured to determine the pulse signal in the second very high frequency radiation pulse signal whose waveform difference with the reference pulse signal is within a first set range as a first comparison pulse signal, and determine the pulse signal in the third very high frequency radiation pulse signal whose waveform difference with the reference pulse signal is within a second set range as a second comparison pulse signal; a matching module, which is configured to move both the first comparison pulse signal and the second comparison pulse signal to the position corresponding to the reference pulse signal using the cross-correlation algorithm to obtain a pulse signal set, wherein the pulse signal set comprises a matched first comparison pulse signal, a matched second comparison pulse signal and a matched reference pulse signal; and a positioning module, which is configured to cover each pulse signal in the pulse signal set at the same time using a sliding window with a set width to determine the position of the lightning radiation source.

According to a specific embodiment provided by the present disclosure, the present disclosure discloses the following technical effects: the present disclosure extracts pulse signals in a set time period from a first very high frequency radiation pulse signal as reference pulse signals, extracts signals similar to the reference pulse signals from a second very high frequency radiation pulse signal and a third very high frequency radiation pulse signal, respectively, matches the extracted similar signals with the reference signals using a cross-correlation algorithm, only uses the extracted reference pulse signal for matching and positioning without using the acquired complete first very high frequency radiation pulse signals, and only selects the corresponding peak time when the pulse peaks set in three pulse signals appear in the window at the same time to calculate the position of the lightning radiation source, so that the first very high frequency radiation pulse signal will not participate in positioning repeatedly, and the positioning accuracy of the interferometer for the lightning radiation source is improved.

### BRIEF DESCRIPTION OF THE DRAWINGS

In order to explain the embodiments of the present disclosure or the technical scheme in the prior art more clearly, the drawings needed in the embodiments will be briefly introduced hereinafter. Obviously, the drawings in the following description are only some embodiments of the present disclosure. For those skilled in the art, other drawings can be obtained according to these drawings without paying creative labor.

FIG. 1 is a flowchart of a broadband interferometer lightning positioning method based on pulse matching according to Embodiment 1 of the present disclosure;

FIG. 2 is a structural schematic diagram of a broadband interferometer lightning positioning system based on pulse matching according to Embodiment 1 of the present disclosure;

FIG. 3 is a site layout diagram of a broadband very high frequency interferometer and a fast electric field change antenna erected near Kennedy Space Center in 2016 according to Embodiment 2 of the present disclosure;

FIG. 4 illustrates a background noise map (a) with a length of 1700 sampling points according to Embodiment 2 of the present disclosure, a spectrum diagram (b) of a background noise in the background noise map (a), a partial enlarged diagram (c) of the background noise map (a), and a partial enlarged diagram (d) of the spectrum diagram (b);

FIG. 5 illustrates a pulse diagram (a) of a very high frequency radiation pulse signal with a length of 1700 sampling points according to Embodiment 2 of the present disclosure, a spectrum diagram (b) of a very high frequency radiation pulse signal in the pulse diagram (a), and a partial enlarged diagram (c) of the pulse diagram (a);

FIG. 6 illustrates a pulse diagram (a) of a filtered part of a background noise signal in the background noise map (a) of FIG. 4 after being subjected to band-pass filtering, a pulse diagram (b) of a retained part of a background noise signal in the pulse diagram (a) after being subjected to band-pass filtering, a spectrum diagram (c) of the pulse diagram (a), and a spectrum diagram (d) of the pulse diagram (b);

FIG. 7 illustrates a pulse diagram (a) of a filtered part of a lightning very high frequency radiation pulse signal in the pulse diagram (a) of FIG. 5 after being subjected to band-pass filtering, a pulse diagram (b) of a retained part of a lightning very high frequency radiation pulse signal in the pulse diagram (a) of FIG. 5 after being subjected to band-pass filtering, a spectrum diagram (c) of the pulse diagram (a) of FIG. 7, and a spectrum diagram (d) of the pulse diagram (b) of FIG. 7;

FIG. 8 illustrates a pulse diagram (a) of a very high frequency radiation pulse signal selected on the antenna chA according to Embodiment 2 of the present disclosure, a pulse diagram (b) of a very high frequency radiation pulse signal selected on the antenna chB according to Embodiment 2 of the present disclosure, and a pulse diagram (c) of a very high frequency radiation pulse signal selected on the antenna chC according to Embodiment 2 of the present disclosure;

FIG. 9 illustrates a pulse diagram (a) of a very high frequency radiation pulse signal obtained by matching a very high frequency radiation pulse signal selected on the antenna chA and a very high frequency radiation pulse signal selected on the antenna chB through a generalized cross-correlation algorithm according to Embodiment 2 of the present disclosure, and a pulse diagram (b) of a very high frequency radiation pulse signal obtained by matching a very high frequency radiation pulse signal selected on the antenna chA and a very high frequency radiation pulse signal selected on the antenna chC through a generalized cross-correlation algorithm according to Embodiment 2 of the present disclosure;

FIG. 10 illustrates a geometric schematic diagram (a) for determining the position of a radiation source according to Embodiment 2 of the present disclosure, and a schematic diagram (b) of an evaluation method of a positioning error according to Embodiment 2 of the present disclosure; and

FIG. 11 illustrates a pulse matching result diagram (a) of a very high frequency radiation pulse signal according to Embodiment 2 of the present disclosure through a 40 M-80 M band-pass filter, and a pulse matching result diagram (b) of a very high frequency radiation pulse signal according to Embodiment 2 of the present disclosure through a 20 M-80 M band-pass filter.

### DETAILED DESCRIPTION

The technical scheme in the embodiments of the present disclosure will be described clearly and completely with reference to the drawings in the embodiments of the present disclosure. Obviously, the described embodiments are only some embodiments of the present disclosure, rather than all of the embodiments. Based on the embodiments of the present disclosure, all other embodiments obtained by those skilled in the art without paying creative labor belong to the scope of protection of the present disclosure.

In order to make the above objects, features and advantages of the present disclosure more obvious and understandable, the present disclosure will be further explained in detail with reference to the drawings and specific embodiments.

### EMBODIMENT 1

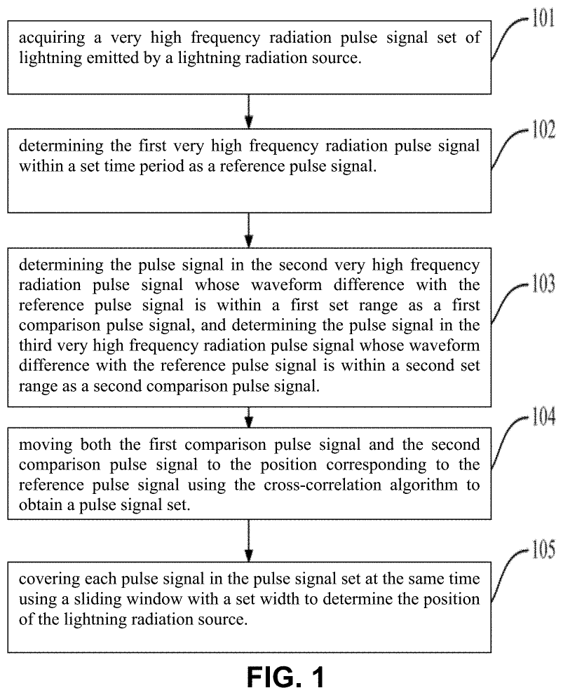

This embodiment provides a broadband interferometer lightning positioning method based on pulse matching. As shown in FIG. 1, the method comprises:

Step 101: acquiring a very high frequency radiation pulse signal set of lightning emitted by a lightning radiation source, wherein the very high frequency radiation pulse signal set comprises a first very high frequency radiation pulse signal, a second very high frequency radiation pulse signal and a third very high frequency radiation pulse signal, and the very high frequency radiation pulse signal set is simultaneously acquired by three antennas forming a broadband very high frequency interferometer;

Step 102: determining the first very high frequency radiation pulse signal within a set time period as a reference pulse signal;

Step 103: determining the pulse signal in the second very high frequency radiation pulse signal whose waveform difference with the reference pulse signal is within a first set range as a first comparison pulse signal, and determining the pulse signal in the third very high frequency radiation pulse signal whose waveform difference with the reference pulse signal is within a second set range as a second comparison pulse signal;

Step 104: moving both the first comparison pulse signal and the second comparison pulse signal to the position corresponding to the reference pulse signal using the cross-correlation algorithm to obtain a pulse signal set, wherein the pulse signal set comprises a matched first comparison pulse signal, a matched second comparison pulse signal and a matched reference pulse signal;

Step 105: covering each pulse signal in the pulse signal set at the same time using a sliding window with a set width to determine the position of the lightning radiation source.

Step 105 specifically comprises:

covering each pulse signal in the pulse signal set at the same time using a sliding window with a set width to determine a peak time set and a pulse waveform set, wherein the peak time set comprises peak time corresponding to each pulse signal when the set pulse peaks of all pulse signals in the pulse signal set appear in the sliding window at the same time, and the pulse waveform set comprises a pulse waveform of each pulse signal when the set pulse peaks of all pulse signals in the pulse signal set appear in the sliding window at the same time;

calculating correlation coefficients among all pulse signals in the pulse signal set to obtain a correlation coefficient set, and determining whether all pulse signals are the same discharge event of the same lightning radiation source according to the correlation coefficient set;

if so, determining a first time difference and a second time difference according to the peak time set, wherein the first time difference is a time difference between the reference pulse signal and the first comparison pulse signal, and the second time difference is a time difference between the reference pulse signal and the second comparison pulse signal;

calculating an azimuth angle and an elevation angle of the lightning radiation source according to the first time difference and the second time difference;

determining the position of the lightning radiation source from the azimuth angle and the elevation angle.

Calculating an azimuth angle and an elevation angle of the lightning radiation source according to the first time difference and the second time difference specifically comprises:

determining a connecting line between a first antenna in the broadband very high frequency interferometer and a second antenna in the broadband very high frequency interferometer as a first baseline, and determining a connecting line between a first antenna in the broadband very high frequency interferometer and a third antenna in the broadband very high frequency interferometer as a second baseline, wherein the first antenna is used to acquire the first very high frequency radiation pulse signal, the second antenna is used to acquire the second very high frequency radiation pulse signal, and the third antenna is used to acquire the third very high frequency radiation pulse signal;

if the first baseline is orthogonal to the second baseline, calculating the azimuth angle and the elevation angle of the lightning radiation source according to the formula

$$Az = arctan ( \frac{{τ}_{d 1}}{{τ}_{d 2}} )$$

$$El = arccos ( \frac{c}{d} \sqrt{{τ}_{d 1}^{2} + {τ}_{d 2}^{2}} ) ,$$

where c is the speed of light, d is the length of baseline, τ_{d1} is the first time difference, τ_{d2} is the second time difference, Az is the azimuth angle of the lightning radiation source, and El is the elevation angle of the lightning radiation source;

if the first baseline is not orthogonal to the second baseline and the included angle between the first baseline and the due north direction is not 0, calculating the azimuth angle and the elevation angle of the lightning radiation source according to the formula

$$Az = {Az}_{1} + arctan ( \frac{{τ}_{d 1} cos ( Δ θ ) - {τ}_{d 2}}{{τ}_{d 2} sin ( Δ θ )} )$$

$$El = arccos ( \frac{c}{d} \sqrt{\frac{{τ}_{d 1}^{2} + {τ}_{d 2}^{2} - 2 {τ}_{d 1} {τ}_{d 2} cos ( Δ θ )}{{sin}^{2} ( Δ θ )}} ) ,$$

where Δθ=Az₁−Az₂ is the included angle between the first baseline and the second baseline, Az1 is the included angle between the first baseline and the due north direction, and Az2 is the included angle between the second baseline and the due north direction.

Prior to step 103, the method further comprises:

determining the second very high frequency radiation pulse signal within the set time period as a first main window pulse signal, and determining the third very high frequency radiation pulse signal within the set time period as a second main window pulse signal;

determining the second very high frequency radiation pulse signal in a first time period as a first auxiliary window pulse signal, determining the second very high frequency radiation pulse signal in a second time period as a second auxiliary window pulse signal, determining the third very high frequency radiation pulse signal in a first time period as a third auxiliary window pulse signal, and determining the third very high frequency radiation pulse signal in a second time period as a fourth auxiliary window pulse signal, wherein the first time period is the time period before the set time period, the second set time period is the time period after the set time period, and the first time period, the set time period and the second set time period form a continuous time period;

determining the first main window pulse signal, the first auxiliary window pulse signal and the second auxiliary window pulse signal as the selected second very high frequency radiation pulse signal, and determining the second main window pulse signal, the third auxiliary window pulse signal and the fourth auxiliary window pulse signal as the selected third very high frequency radiation pulse signal.

Prior to step 102, the method further comprises:

filtering the very high frequency radiation pulse signal of the lightning to obtain a filtered very high frequency radiation pulse signal.

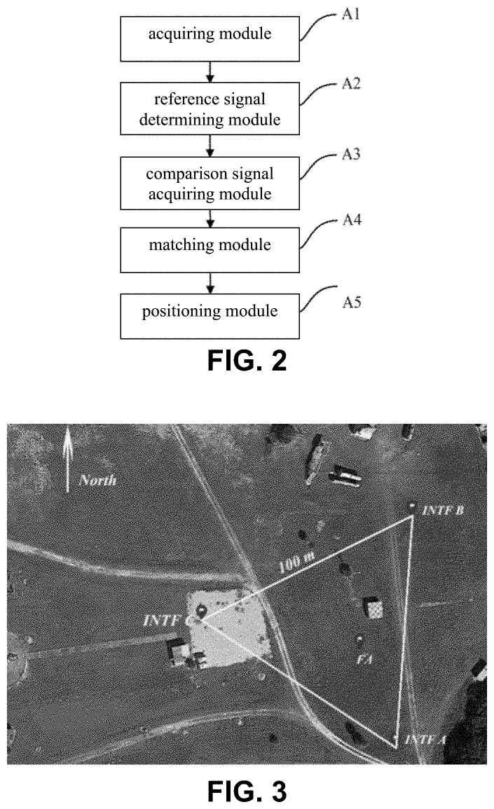

Corresponding to the above method, this embodiment further provides a broadband interferometer lightning positioning system based on pulse matching. As shown in FIG. 2, the system comprises:

an acquiring module, which is configured to acquire a very high frequency radiation pulse signal set of lightning emitted by a lightning radiation source, wherein the very high frequency radiation pulse signal set comprises a first very high frequency radiation pulse signal, a second very high frequency radiation pulse signal and a third very high frequency radiation pulse signal, and the very high frequency radiation pulse signal set is simultaneously acquired by three antennas forming a broadband very high frequency interferometer;

a reference signal determining module, which is configured to determine the first very high frequency radiation pulse signal within a set time period as a reference pulse signal;

a comparison signal acquiring module, which is configured to determine the pulse signal in the second very high frequency radiation pulse signal whose waveform difference with the reference pulse signal is within a first set range as a first comparison pulse signal, and determine the pulse signal in the third very high frequency radiation pulse signal whose waveform difference with the reference pulse signal is within a second set range as a second comparison pulse signal;

a matching module, which is configured to move both the first comparison pulse signal and the second comparison pulse signal to the position corresponding to the reference pulse signal using the cross-correlation algorithm to obtain a pulse signal set, wherein the pulse signal set comprises a matched first comparison pulse signal, a matched second comparison pulse signal and a matched reference pulse signal;

a positioning module, which is configured to cover each pulse signal in the pulse signal set at the same time using a sliding window with a set width to determine the position of the lightning radiation source.

As a preferable embodiment, the positioning module specifically comprises:

a set determining module, which is configured to cover each pulse signal in the pulse signal set at the same time using a sliding window with a set width to determine a peak time set and a pulse waveform set, wherein the peak time set comprises peak time corresponding to each pulse signal when the set pulse peaks of all pulse signals in the pulse signal set appear in the sliding window at the same time, and the pulse waveform set comprises a pulse waveform of each pulse signal when the set pulse peaks of all pulse signals in the pulse signal set appear in the sliding window at the same time;

a first determination unit, which is configured to calculate correlation coefficients among all pulse signals in the pulse signal set to obtain a correlation coefficient set, and determine whether all pulse signals are the same discharge event of the same lightning radiation source according to the correlation coefficient set;

a time difference calculating unit, which is configured to, if so, determine a first time difference and a second time difference according to the peak time set, wherein the first time difference is a time difference between the reference pulse signal and the first comparison pulse signal, and the second time difference is a time difference between the reference pulse signal and the second comparison pulse signal;

an angle calculating unit, which is configured to calculate an azimuth angle and an elevation angle of the lightning radiation source according to the first time difference and the second time difference;

a positioning unit, which is configured to determine the position of the lightning radiation source from the azimuth angle and the elevation angle.

As a preferable embodiment, the system further comprises:

a main window pulse signal acquiring module, which is configured to determine the second very high frequency radiation pulse signal within the set time period as a first main window pulse signal, and determine the third very high frequency radiation pulse signal within the set time period as a second main window pulse signal;

an auxiliary window pulse signal acquiring module, which is configured to determine the second very high frequency radiation pulse signal in a first time period as a first auxiliary window pulse signal, determine the second very high frequency radiation pulse signal in a second time period as a second auxiliary window pulse signal, determine the third very high frequency radiation pulse signal in a first time period as a third auxiliary window pulse signal, and determine the third very high frequency radiation pulse signal in a second time period as a fourth auxiliary window pulse signal, wherein the first time period is the time period before the set time period, the second set time period is the time period after the set time period, and the first time period, the set time period and the second set time period form a continuous time period;

a selecting module, which is configured to determine the first main window pulse signal, the first auxiliary window pulse signal and the second auxiliary window pulse signal as the selected second very high frequency radiation pulse signal, and determine the second main window pulse signal, the third auxiliary window pulse signal and the fourth auxiliary window pulse signal as the selected third very high frequency radiation pulse signal.

As a preferable embodiment, the system further comprises:

a filtering module, which is configured to filter the very high frequency radiation pulse signal of the lightning to obtain a filtered very high frequency radiation pulse signal.

As a preferable embodiment, the angle calculating unit comprises:

a baseline determining subunit, which is configured to determine a connecting line between a first antenna in the broadband very high frequency interferometer and a second antenna in the broadband very high frequency interferometer as a first baseline, and determine a connecting line between a first antenna in the broadband very high frequency interferometer and a third antenna in the broadband very high frequency interferometer as a second baseline, wherein the first antenna is used to acquire the first very high frequency radiation pulse signal, the second antenna is used to acquire the second very high frequency radiation pulse signal, and the third antenna is used to acquire the third very high frequency radiation pulse signal;

a first angle calculating subunit, which is configured to, if the first baseline is orthogonal to the second baseline, calculate the azimuth angle and the elevation angle of the lightning radiation source according to the formula

$$Az = arctan ( \frac{{τ}_{d 1}}{{τ}_{d 2}} )$$

$$El = arccos ( \frac{c}{d} \sqrt{{τ}_{d 1}^{2} + {τ}_{d 2}^{2}} ) ,$$

where c is the speed of light, is the length of baseline, τ_{d1} is the first time difference, τ_{d2} is the second time difference, Az is the azimuth angle of the lightning radiation source, and El is the elevation angle of the lightning radiation source;

a second angle calculating subunit, which is configured to, if the first baseline is not orthogonal to the second baseline and the included angle between the first baseline and the due north direction is not 0, calculate the azimuth angle and the elevation angle of the lightning radiation source according to the formula

$$Az = {Az}_{1} + arctan ( \frac{{τ}_{d 1} cos ( Δ θ ) - {τ}_{d 2}}{{τ}_{d 2} sin ( Δ θ )} )$$

$$El = arccos ( \frac{c}{d} \sqrt{\frac{{τ}_{d 1}^{2} + {τ}_{d 2}^{2} - 2 {τ}_{d 1} {τ}_{d 2} cos ( Δ θ )}{{sin}^{2} ( Δ θ )}} ) ,$$

where Δθ=Az₁−Az₂ is the included angle between the first baseline and the second baseline, Az1 is the included angle between the first baseline and the due north direction, and Az2 is the included angle between the second baseline and the due north direction.

### EMBODIMENT 2

The observation data used in this embodiment comes from the broadband very high frequency interferometer deployed near Kennedy Space Center in 2016-2017. The broadband very high frequency interferometer consists of three broadband very high frequency (16-88 MHz) flat receiving antennas (INTF A, INTF B and INTF C in the figure) under the baseline condition of an equilateral triangle of 100 meters. The antenna layout is shown in FIG. 3, which is different from the orthogonal baseline layout adopted in previous similar observations.

Using the existing positioning technology, the broadband very high frequency interferometer of New Mexico Tech can continuously and accurately determine the two-dimensional arrival direction of very high frequency radiation events with sub-microsecond time resolution. The time series waveforms of each receiver and Fast Antenna (FA) are recorded synchronously at a sampling rate of 180 ms/s and a sampling accuracy of 16 bits. The waveform of the broadband very high frequency interferometer is post-processed, and the exposure very high frequency image with 1.4 μs (with 256 sampling points as the window width) is usually generated, and the offset between the images is 0.35 μs (with 64 sampling points as the step progressive window). The centroid or brightest pixel of each image is mapped in space and time to determine the two-dimensional (0.35 μs) development process of lightning radiation source. The positioning result for comparison in this embodiment is obtained by the positioning technology with the above parameters.

1. Introduction of Algorithm:

Similar to the improvement of the positioning ability of the low-frequency lightning detection system in the prior art, the improvement of the positioning ability is always based on the accurate analysis of the characteristics of the detection system and the detected electric field signal. According to the characteristics of lightning electric field signal, the empirical mode decomposition (EMD) method is introduced into the analysis of lightning electric field signal, and then a ensemble empirical mode decomposition method is proposed to perform double-sided bidirectional mirror extension on the signal to be analyzed, so as to optimize the signal characteristics and improve the noise reduction performance of the algorithm, especially to greatly improve the extraction accuracy of a weak pulse signal.

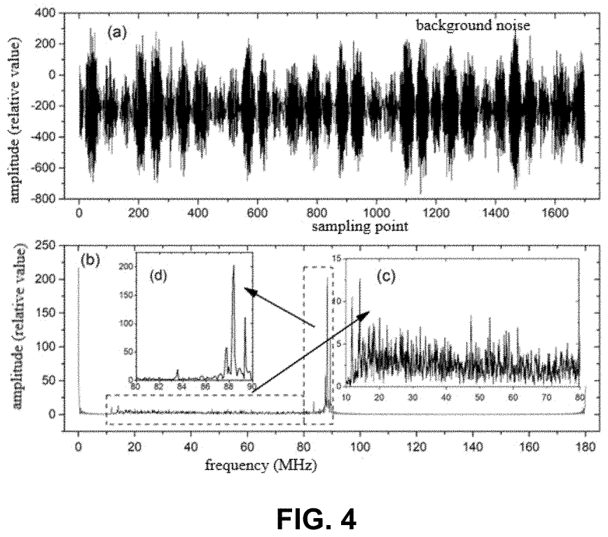

Here, we give the waveform of a very high frequency radiation pulse signal of a two-stage interferometer as an example of signal feature analysis using Hilbert-Huang transform with the ensemble empirical mode decomposition method (EEMD) based on double-sided bidirectional mirror extension (DBM_EEMD) as the kernel. The first thing to know is the background noise acquired by the detection system, which is a background noise (the background noise map (a) of FIG. 4) with a length of 1700 sampling points (9.44 μs) and its spectrum (spectrum diagram (b) of FIG. 4) as shown in FIG. 4. From the spectral band analysis of the background noise shown in FIG. 4(b), it can be seen that the background noise comes from the following aspects: 0-line drift of the signal, white noise in the acquisition frequency band (as shown in the partial enlarged diagram (c) of FIG. 4), which may be superimposed with weak noise from other sources), and strong broadcast signals in multiple channels near 89 MHz (the partial enlarged diagram (d) of FIG. 4). These three kinds of noise signals will have a serious impact on positioning by calculating the time difference based on generalized cross-correlation technology.

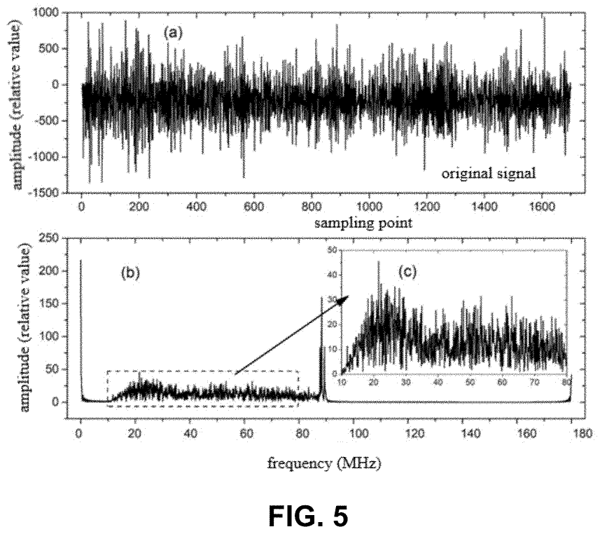

FIG. 5 shows the waveform (a) of a very high frequency radiation pulse signal with the same length of 1700 sampling points (9.44 μs), and the radiation signal is weak on the whole. It can be seen from the spectrum analysis in the spectrum diagram (b) of FIG. 5 that there are two strong noise sources in the background noise, in which 0-line drift and broadcast signal noise exist stably, and it is also found that the background noise has not changed greatly in a large number of analysis and comparison of the detection signals. The partial enlarged diagram (c) of FIG. 5 shows the spectral distribution characteristics of very high frequency radiation signals in the acquired frequency band, comprising weak white noise signals covering the whole frequency band (there may be noises from other sources with weak amplitude). In addition, it can be seen from the partial enlarged diagram (c) of FIG. 5 that there are relatively low frequency signals and noises with relatively large amplitude below 40 MHz (i.e., the relatively low frequency band within the detection band). In the research of the prior art, it is found that in the process of matching pulse signals and calculating the pulse peak time difference, the relatively low frequency fluctuation in the detection frequency band has great interference to the accurate extraction of pulse signal information.

1.1 DBM_EEMD Noise Reduction of Signals

Through the above signal feature analysis, after mastering the main features of the detection signal, we use DBM_EEMD algorithm to construct a band-pass filter, which only retains the signal component of 40-80 MHz in the detection signal. This can effectively improve the accuracy of waveform matching and help to obtain more accurate pulse peak time, which can be used to calculate the time difference of the same pulse signal between different antennas, and then realize the accurate positioning of the radiation source.

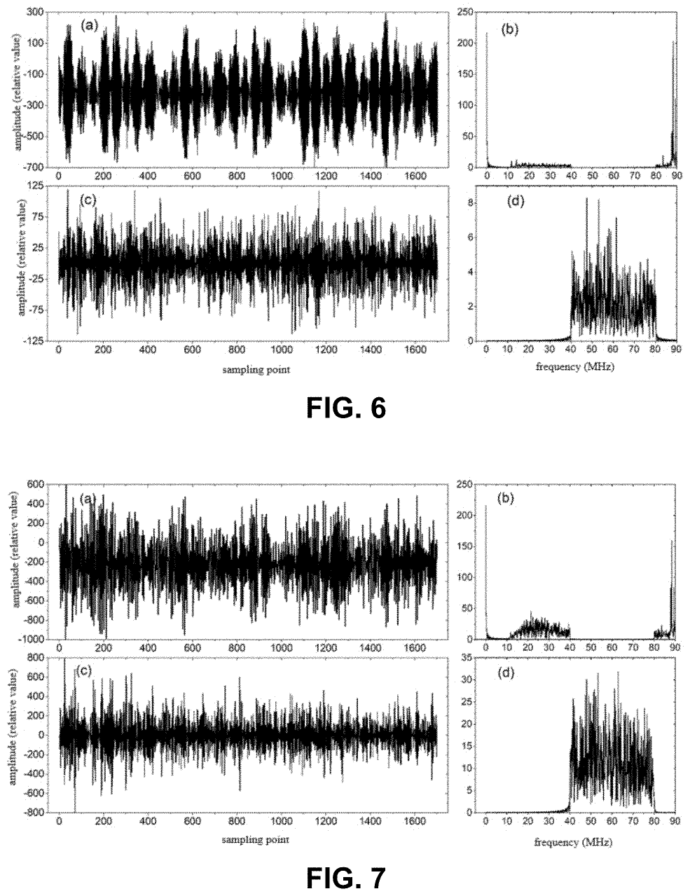

The pulse diagram (a) of FIG. 6 contains the 0-line drift, broadcast signals and white noise components below 40 MHz in the background noise (the spectrum distribution is shown in the pulse diagram (b) of FIG. 6). Compared with the simple shape of the original waveform in background noise map (a) of FIG. 4, it can be seen that the band-pass filter constructed with DBM_EEMD can effectively remove most of the noise components. The absolute component of the background noise at 40-80 MHz (the frequency spectrum is shown in the spectrum diagram (d) of FIG. 6) after being subjected to band-pass filtering is very small (as shown in the spectrum diagram (c) of FIG. 6), and the range of the background noise (the difference between the maximum value and the minimum value) is less than 250 (the range of the acquired signal is 216).

Although the noisy very high frequency radiation pulse signal will lose some real signal components after being subjected to band-pass filtering (the filtered part is shown in the pulse diagram (a) of FIG. 7), and its frequency spectrum is shown in the pulse diagram (b) of FIG. 7), but this abandonment of some signal components is valuable. Only a very small number of noise signal components remain in the signal, which can minimize the influence of the noise signal (the signal after being subjected to band-pass filtering is shown in the spectrum diagram (c) of FIG. 7), and its frequency spectrum is shown in the pulse diagram (b) of FIG. 7). The signal components after being subjected to band-pass filtering are relatively simple and the bandwidth is narrow, which can effectively improve the accuracy of signal matching and is helpful to significantly improving the richness and accuracy of pulse information extraction in waveform.

1.2 Cross-Correlation Matching of Signals

After analyzing the characteristics of the original signal and using the band-pass filter constructed by DBM_EEMD to perform quality control and signal reconstruction on the original signal, this embodiment uses the generalized cross-correlation technology to match the signals on different antennas, so as to prepare for further pulse signal identification and matching.

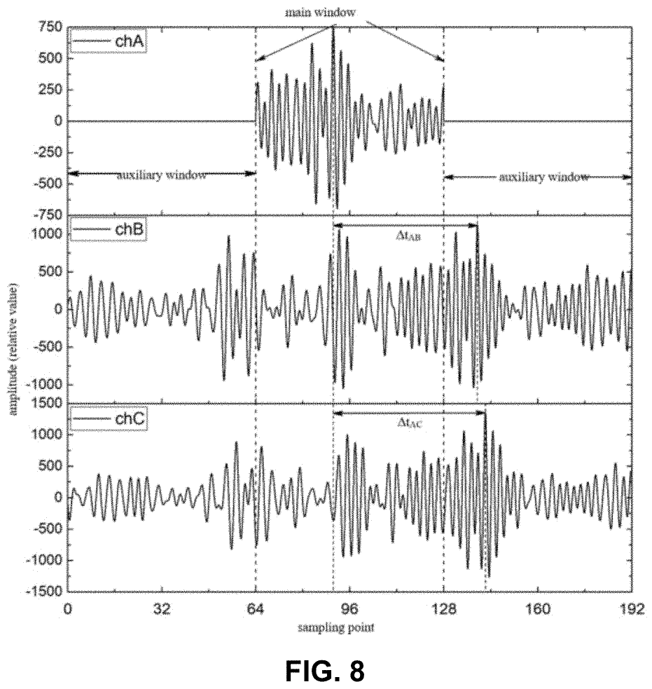

Different from the window matching method of the generalized cross-correlation technology, the technical route proposed and adopted in this embodiment introduces the concept of an auxiliary window. As shown in FIG. 8, a signal with a length of 192 sampling points is divided into three parts: a main window with a length of 64 sampling points located in the middle of the signal (taking the observation in KSC in 2016 as an example, the three antennas form an equilateral triangle with a baseline length of 100 m. When the radiation signal generated by lightning is received by the broadband very high frequency interferometer antenna, the generated time difference will not be greater than the time required for the speed of light to travel 100 m, that is, the deviation corresponding to about 60 sampling points at the sampling rate of 330 ns and 180 M (time resolution of 5.5 ns). For the fault tolerance and universality of the algorithm, 64 is taken as the length of the auxiliary window. In the algorithm, the main window should keep the weight similar to that of the auxiliary window, so the length of the main window is also set to 64 sampling points) and an auxiliary window with the length of 64 sampling points located on both sides of the main window. Specifically, as shown in the pulse diagram (a) of FIG. 8, the antenna chA is taken as the central station, and 64 sampling points are intercepted as the main window. An auxiliary window with zero value is constructed on both sides of the main window, as shown in the pulse diagram (a) of FIG. 8 and the pulse diagram (c) of FIG. 8. The main window intercepts the real signal at the same time as chA on chB and chC, but the difference is that their auxiliary window also intercepts the real signal with a length of 64 sampling points which extends to both sides. The length of the auxiliary window depends on the length of the longest baseline formed by the broadband very high frequency interferometer antenna.

This setting of the main window and the auxiliary window has many advantages. First of all, signals will not participate in positioning repeatedly. This is because, on the time axis of the central station (chA), the signal is traversed at 64 sampling points (352 ns). A signal whose shape is as consistent as possible with that of the main window signal of chA is found out in the signals of other antennas (a main window+2 auxiliary windows) by the generalized cross-correlation method for subsequent pulse waveform matching and positioning calculation. The signal on chA will not be reused, so there will be no repeated positioning information. On the other hand, scholars usually expect to obtain more information of radiation sources by further reducing the size of the window, but the baseline length of the broadband very high frequency interferometer usually limits the maximum time difference between different antennas for the same discharge event, which limits the minimum window width that can be used by the window matching algorithm. The combination of the main window and the auxiliary window proposed in this embodiment actually breaks through the above limitations. More importantly, setting only the main window but not the auxiliary window on chA can significantly improve the accuracy of window matching by generalized cross-correlation, and further improve the accuracy of pulse signal matching and information extraction on a smaller time scale.

1.3 Pulse Extraction Under a Microscale Window

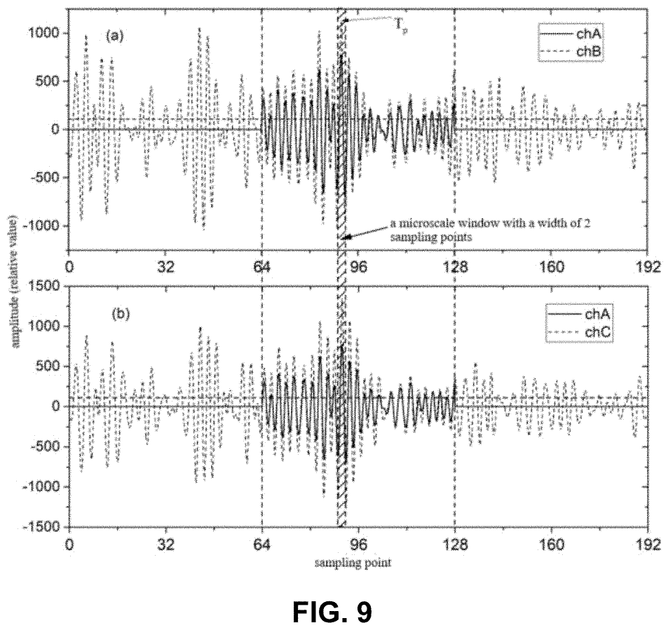

As shown in FIG. 8, the maximum correlation coefficients of chB, chC and chA appear after shifting chB and chC to the left by ΔtAB and ΔtAC, respectively, so as to realize window pairing. The result is shown in FIG. 9. In FIG. 9, a pulse diagram (a) of a very high frequency radiation pulse signal obtained by matching a very high frequency radiation pulse signal selected on the antenna chA and a very high frequency radiation pulse signal selected on the antenna chB through a generalized cross-correlation algorithm. In FIG. 9, a pulse diagram (b) of a very high frequency radiation pulse signal obtained by matching a very high frequency radiation pulse signal selected on the antenna chA and a very high frequency radiation pulse signal selected on the antenna chC through a generalized cross-correlation algorithm. In the existing positioning scheme, this time differences ΔtAB and ΔtAC are used to obtain the two-dimensional information of “a radiation source”. As mentioned earlier, in the window-based positioning technology, the correlation of time series in the window on two antennas mainly depends on one or even several strong pulse signals, and due to the influence of other signals in the window, the time delay calculated by generalized cross-correlation between antennas usually deviates from the peak time of the strongest pulse in the window.

In this way, in order to accurately pair the pulse signals on different antennas in the main window, more steps and constraints are needed for realization:

a. First, the time of all the pulse peaks whose peaks (local maxima) are larger than the threshold (as shown by the horizontal dashed line in FIG. 9) in the main window of the central station chA (take the strongest pulse on chA shown in the pulse diagram of FIG. 9 as an example, and its peak time is Tp).

b. With Tp as the center, a microscale window with a width of 11 ns is constructed to cover chA, chB and chC at the same time, and whether pulse peaks appear in the window range is detected on chB and chC. In the 11 ns window, when pulses are detected on all three antenna signals, the next step is continued.

c. The three preliminarily paired pulses in step b are similarly determined, that is, the peak time (TpA, TpB, TpC) of the three successfully paired pulses is taken as the center to intercept the waveforms with a width of 11 ns, and the correlation coefficient between the pulse waveforms is calculated. Only when the correlation coefficient between every two pulse waveforms is greater than 0.8, it is considered that the above three pulse signals come from the same “discharge” event.

d. The peak moments of the three successfully paired pulses are TpA, TpB, TpC. Taking chA and chB as examples, the time difference of the same pulse signal arriving at A and B antennas is Δt_{AB}=T_{pA}−T_{pB} and the three groups of baselines formed by the three antennas have three groups of time differences τᵢⱼ, so as to obtain the two-dimensional positioning result of the pulse radiation source by an interference method.

2. Nonlinear Least Square Solution

Usually, in order to obtain the two-dimensional information (an azimuth angle and an elevation angle) of lightning radiation source, a set of interferometer antennas with orthogonal baselines are needed to measure the time difference of the radiation source signals reaching the antenna. Then the azimuth angle and the elevation angle of the radiation source are calculated with the following formula:

$$Az = arctan ( \frac{{τ}_{d 1}}{{τ}_{d 2}} ) \\ El = arccos ( \frac{c}{d} \sqrt{{τ}_{d 1}^{2} + {τ}_{d 2}^{2}} ) , \qquad ( 1 )$$

where d is the length of the baseline, and τ_{d1} and τ_{d2} are the time difference of lightning radiation sources reaching the antenna on two orthogonal baselines.

However, it is very difficult to ensure that the antenna layout is completely orthogonal and the baseline direction accurately points to the reference direction. Therefore, for the non-orthogonal antenna layout in which the baseline 1 (the baseline formed by chA and chB) does not point to the azimuth angle 0 (Az1=0), the azimuth angle and the elevation angle of the radiation source are calculated by the following correction formula:

$$Az = {Az}_{1} + arctan ( \frac{{τ}_{d 1} cos ( Δ θ ) - {τ}_{d 2}}{{τ}_{d 2} sin ( Δ θ )} ) \\ El = arccos ( \frac{c}{d} \sqrt{\frac{{τ}_{d 1}^{2} + {τ}_{d 2}^{2} - 2 {τ}_{d 1} {τ}_{d 2} cos ( Δ θ )}{{sin}^{2} ( Δ θ )}} ) \qquad ( 2 )$$

where Δθ=Az₁−Az₂ is the included angle between baselines. Formula 2 is very suitable for correcting the angular deviation of the deployed antenna array, but it is not suitable for solving the detection system using more than two baselines. For an array with N≥3 antennas, the number of baseline combinations is N(N−1)/2, and solving using Formula 2 will often produce poor results. In addition, the result of solving using Formula 2 is not convenient for the evaluation of a positioning result error.

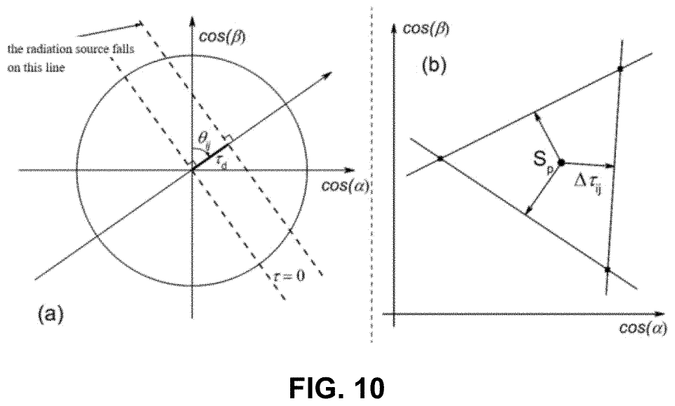

Geometrically, Formula 2 solves the intersection of two straight lines in the sky cosine projection, as shown in the geometric schematic diagram (a) of FIG. 10. The arrival time difference τ_{d} between two antennas defines a straight line perpendicular to the baseline in cosine projection, namely:

$$cos ( α ) sin ( {θ}_{ij} ) + cos ( β ) cos ( {θ}_{ij} ) = \frac{c {τ}_{ij}}{{d}_{ij}} \qquad ( 3 )$$

where cos(α) and cos(β) are directional cosines, θᵢⱼ is the included angle between the baseline and the due north direction (see FIG. 3), dᵢⱼ is the length of the baseline formed by the ith and jth antennas, and τᵢⱼ is the arrival time difference of the same radiation source on the ith and jth antennas. No matter how the time delay is determined, Equation 2 applies as long as the time delay is accurate. cos(α) and cos(β) are coordinates on the geometric schematic diagram (a) of FIG. 10 (the cosine projection plane, which is a special projection mode). The line with arrow passing through the center of the circle indicates the direction of the baseline, and the thick solid line between the two dashed lines is

$$\frac{c {τ}_{ij}}{{d}_{ij}} ,$$

that is, the ratio of the length τᵢⱼ of propagation time of speed of light to the corresponding baseline length. For the solution of Formula (3), we use the nonlinear least square method, which is widely used in the three-dimensional lightning location system. For the interferometer detection system, the number of baseline combinations formed by the array of N antennas is N(N−1)/2, so as to obtain N(N−1)/2 equation sets in the form of (3). There are two unknown parameters cos(α) and cos(β) in Formula (3), so when three antennas form three baselines, the super solution of Formula (3) can be obtained. The result Sp obtained by the nonlinear least square method is the projection of the radiation source on the cosine plane, satisfying:

$${χ}^{2} = \frac{2}{N ( N - 1 )} {{\sum }_{i = 1 , N}}_{j = i + 1 , N} \frac{{( {τ}_{ij}^{obs} - {τ}_{ij}^{fit} )}^{2}}{Δ {t}_{rms}^{2}} = \frac{2}{N ( N - 1 )} {{\sum }_{i = 1 , N}}_{j = i + 1 , N} \frac{{( {Δτ}_{ij} )}^{2}}{Δ {t}_{rms}^{2}} \qquad ( 4 )$$

where N represents the antenna number of interferometers, and Δtrms represents the error level of pulse peak time extraction. The estimated value of the time error of the broadband very high frequency interferometer at the sampling frequency of 180 M is not more than 5.5 ns (one sampling point). τᵢⱼ^{fit} represents the arrival time difference of the same radiation source on the ith and jth antennas calculated by nonlinear least squares iteration. A set of cos(α) and cos(β) is obtained by nonlinear least square method, so that the value of Formula (4) is minimum (as shown in the schematic diagram (b) of FIG. 10). According to the two-dimensional coordinate Sₚ (cos(α), cos(β) on the cosine projection plane, the spatial two-dimensional coordinates of the pulse radiation source can be calculated:

$$Az = arctan ( \frac{cos ( α )}{cos ( β )} ) \\ El = arccos ( \frac{cos ( β )}{cos ( Az )} ) \qquad ( 5 )$$

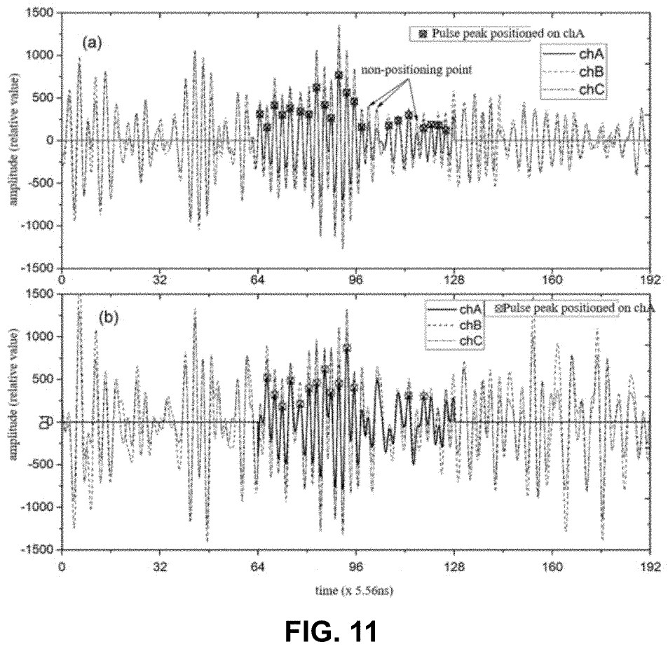

After the above steps, the DBM_EEMD method is used to control the quality of the original signal. By combining the main window with the auxiliary window, the waveform matching of different antenna signals is realized by using the generalized cross-correlation method. Under the microscale window (11 ns), the accurate pairing of pulse signals and the extraction of arrival time difference are realized by threshold constraint and similarity constraint of pulse signals. Finally, the spatial two-dimensional coordinates of the matched pulse radiation source are obtained by the nonlinear least square method, which can obtain richer lightning discharge information than the window-based positioning method. Taking the main window waveform of chA with a length of 64 sampling points (duration of 0.355 μs) shown in FIG. 8 as an example, the window-based positioning method can obtain two radiation source positioning results when 32 sampling points are taken as the step size, and can obtain only one radiation source positioning result when the step size is 64 sampling points. With the positioning method based on full pulse matching proposed in this embodiment, the richness of positioning results is greatly improved. Especially the band-pass filter constructed by the DBM_EEMD method introduced in this embodiment plays an important role in extracting pulse signals. As shown in the pulse matching result diagram (a) of FIG. 11, when the signal is referred to as a relatively narrow-band signal after being subjected to 40-80 M band-pass filtering, the pulse characteristics in the signal are highlighted, and a total of 21 groups of pulses meeting the screening threshold are successfully matched and located within a window with the duration of 0.355 μs. As shown in the pulse matching result diagram (b) of FIG. 11, when the signal is subjected to 20-80 M band-pass filtering, the upper limit frequency of the signal is four times of the lower limit frequency. The superposition of relatively low-frequency signals and relatively high-frequency signals makes the characteristics of very high frequency radiation signals more complex. Only 14 groups of pulses meet the screening threshold and are successfully matched and located. This is because when signals of different frequency bands arrive at different antennas, due to the difference in arrival time, the signals superimposed with them may come from different radiation sources or the same radiation source but have different phases when superimposed, producing different signal amplification or cancellation effects, so that the signal characteristics are more complex. Noise signals outside the signal acquisition frequency band (whose signal amplitude is much higher than that of white noise signals) have a serious impact on waveform matching and extraction of peak time of pulse signals. Without quality control of original signals, only two pulses of the example signal in FIG. 11 are matched and located.

In this specification, each embodiment is described in a progressive manner, and each embodiment focuses on the differences from other embodiments. It is sufficient to refer to the same and similar parts between each embodiment. For the system disclosed in the embodiment, because it corresponds to the method disclosed in the embodiment, the description is relatively simple, and the relevant points can be found in the description of the method.

In the present disclosure, a specific example is applied to illustrate the principle and implementation of the present disclosure. The explanation of the above embodiments is only used to help understand the method and its core idea of the present disclosure; at the same time, according to the idea of the present disclosure, there will be some changes in the specific implementation and application scope for those skilled in the art. To sum up, the contents of this specification should not be construed as limiting the present disclosure.

1. A broadband interferometer lightning positioning method based on pulse matching, the method comprising:
simultaneously acquiring, via three antennas forming a broadband very high frequency interferometer, a very high frequency radiation pulse signal set of lightning emitted by a lightning radiation source, wherein the very high frequency radiation pulse signal set comprises a first very high frequency radiation pulse signal, a second very high frequency radiation pulse signal, and a third very high frequency radiation pulse signal;
determining the first very high frequency radiation pulse signal within a set time period as a reference pulse signal;
determining the pulse signal in the second very high frequency radiation pulse signal whose waveform difference with the reference pulse signal is within a first set range as a first comparison pulse signal, and determining the pulse signal in the third very high frequency radiation pulse signal whose waveform difference with the reference pulse signal is within a second set range as a second comparison pulse signal;
moving both the first comparison pulse signal and the second comparison pulse signal to a position corresponding to the reference pulse signal using a cross-correlation algorithm to obtain a pulse signal set comprising a matched first comparison pulse signal, a matched second comparison pulse signal, and a matched reference pulse signal; and
simultaneously covering each pulse signal in the pulse signal set using a sliding window with a set width to determine a position of the lightning radiation source.

2. The method of claim 1, wherein simultaneously covering each pulse signal in the pulse signal set comprises:
simultaneously covering each pulse signal in the pulse signal set using a sliding window with the set width to determine a peak time set and a pulse waveform set, wherein the peak time set comprises peak time corresponding to each pulse signal when the set pulse peaks of all pulse signals in the pulse signal set simultaneously appear in the sliding window, and the pulse waveform set comprises a pulse waveform of each pulse signal when the set pulse peaks of all pulse signals in the pulse signal set simultaneously appear in the sliding window;
calculating correlation coefficients among all pulse signals in the pulse signal set to obtain a correlation coefficient set, and determining whether all pulse signals are the same discharge event of the same lightning radiation source according to the correlation coefficient set;
determining, when all pulse signals are the same discharge event of the same lightning radiation source according to the correlation coefficient set, a first time difference and a second time difference according to the peak time set, wherein the first time difference is a time difference between the reference pulse signal and the first comparison pulse signal, and the second time difference is a time difference between the reference pulse signal and the second comparison pulse signal;
calculating an azimuth angle and an elevation angle of the lightning radiation source according to the first time difference and the second time difference; and
determining the position of the lightning radiation source from the azimuth angle and the elevation angle.

3. The method of claim 2, wherein calculating the azimuth angle and the elevation angle of the lightning radiation source comprises:
determining, as a first baseline, a connecting line between a first antenna in the broadband very high frequency interferometer and a second antenna in the broadband very high frequency interferometer, and determining, as a second baseline, a connecting line between a first antenna in the broadband very high frequency interferometer and a third antenna in the broadband very high frequency interferometer, wherein the first antenna is used to acquire the first very high frequency radiation pulse signal, the second antenna is used to acquire the second very high frequency radiation pulse signal, and the third antenna is used to acquire the third very high frequency radiation pulse signal;
calculating, when the first baseline is orthogonal to the second baseline, the azimuth angle and the elevation angle of the lightning radiation source according to the formula
$$Az = arctan ( \frac{{τ}_{d 1}}{{τ}_{d 2}} )$$
$$El = arccos ( \frac{c}{d} \sqrt{{τ}_{d 1}^{2} + {τ}_{d 2}^{2}} ) ,$$
where c is the speed of light, d is the length of baseline, τ_{d1} is the first time difference, τ_{d2} is the second time difference, Az is the azimuth angle of the lightning radiation source, and El is the elevation angle of the lightning radiation source;
calculating, when the first baseline is not orthogonal to the second baseline and the included angle between the first baseline and the due north direction is not 0, the azimuth angle and the elevation angle of the lightning radiation source according to the formula
$$Az = {Az}_{1} + arctan ( \frac{{τ}_{d 1} cos ( Δ θ ) - {τ}_{d 2}}{{τ}_{d 2} sin ( Δ θ )} )$$
$$El = arccos ( \frac{c}{d} \sqrt{\frac{{τ}_{d 1}^{2} + {τ}_{d 2}^{2} - 2 {τ}_{d 1} {τ}_{d 2} cos ( Δ θ )}{{sin}^{2} ( Δ θ )}} ) ,$$
where Δθ is the included angle between the first baseline and the second baseline, Δθ=Az₁−Az₂, Az₁ is the included angle between the first baseline and the due north direction, and Az₂ is the included angle between the second baseline and the due north direction.

4. The method of claim 1, further comprising, prior to determining the pulse signal in the second very high frequency radiation pulse signal:
determining the second very high frequency radiation pulse signal within the set time period as a first main window pulse signal, and determining the third very high frequency radiation pulse signal within the set time period as a second main window pulse signal;
determining the second very high frequency radiation pulse signal in a first time period as a first auxiliary window pulse signal, determining the second very high frequency radiation pulse signal in a second time period as a second auxiliary window pulse signal, determining the third very high frequency radiation pulse signal in a first time period as a third auxiliary window pulse signal, and determining the third very high frequency radiation pulse signal in a second time period as a fourth auxiliary window pulse signal, wherein the first time period is the time period before the set time period, the second set time period is the time period after the set time period, and the first time period, the set time period and the second set time period form a continuous time period; and
determining the first main window pulse signal, the first auxiliary window pulse signal, and the second auxiliary window pulse signal as the selected second very high frequency radiation pulse signal, and determining the second main window pulse signal, the third auxiliary window pulse signal, and the fourth auxiliary window pulse signal as the selected third very high frequency radiation pulse signal.

5. The method of claim 1, further comprising, prior to determining the first very high frequency radiation pulse signal:
filtering the very high frequency radiation pulse signal of the lightning to obtain a filtered very high frequency radiation pulse signal.

6. A broadband interferometer lightning positioning system based on pulse matching, comprising:
at least one processor; and
a memory storing instructions that, when executed by the at least one processor, cause the at least one processor to execute operations comprising:
simultaneously acquiring, via three antennas forming a broadband very high frequency interferometer, a very high frequency radiation pulse signal set of lightning emitted by a lightning radiation source, wherein the very high frequency radiation pulse signal set comprises a first very high frequency radiation pulse signal, a second very high frequency radiation pulse signal, and a third very high frequency radiation pulse signal;
determining the first very high frequency radiation pulse signal within a set time period as a reference pulse signal;
determining the pulse signal in the second very high frequency radiation pulse signal whose waveform difference with the reference pulse signal is within a first set range as a first comparison pulse signal, and determining the pulse signal in the third very high frequency radiation pulse signal whose waveform difference with the reference pulse signal is within a second set range as a second comparison pulse signal;
moving both the first comparison pulse signal and the second comparison pulse signal to the position corresponding to the reference pulse signal using the cross-correlation algorithm to obtain a pulse signal set, wherein the pulse signal set comprises a matched first comparison pulse signal, a matched second comparison pulse signal, and a matched reference pulse signal;
simultaneously covering each pulse signal in the pulse signal set using a sliding window with a set width to determine the position of the lightning radiation source.

7. The broadband interferometer lightning positioning system of claim 6, wherein simultaneously covering each pulse signal in the pulse signal set comprises:
simultaneously covering each pulse signal in the pulse signal set using a sliding window with a set width to determine a peak time set and a pulse waveform set, wherein the peak time set comprises peak time corresponding to each pulse signal when the set pulse peaks of all pulse signals in the pulse signal set appear in the sliding window at the same time, and the pulse waveform set comprises a pulse waveform of each pulse signal when the set pulse peaks of all pulse signals in the pulse signal set simultaneously appear in the sliding window;
calculating correlation coefficients among all pulse signals in the pulse signal set to obtain a correlation coefficient set, and determining whether all pulse signals are the same discharge event of the same lightning radiation source according to the correlation coefficient set;
determining, when all pulse signals are the same discharge event of the same lightning radiation source according to the correlation coefficient set, a first time difference and a second time difference according to the peak time set, wherein the first time difference is a time difference between the reference pulse signal and the first comparison pulse signal, and the second time difference is a time difference between the reference pulse signal and the second comparison pulse signal;
calculating an azimuth angle and an elevation angle of the lightning radiation source according to the first time difference and the second time difference;
determining the position of the lightning radiation source from the azimuth angle and the elevation angle.

8. The broadband interferometer lightning positioning system of claim 7, wherein calculating the azimuth angle and the elevation angle of the lightning radiation source comprises:
determining, as a first baseline, a connecting line between a first antenna in the broadband very high frequency interferometer and a second antenna in the broadband very high frequency interferometer, and determining, as a second baseline, a connecting line between a first antenna in the broadband very high frequency interferometer and a third antenna in the broadband very high frequency interferometer, wherein the first antenna is used to acquire the first very high frequency radiation pulse signal, the second antenna is used to acquire the second very high frequency radiation pulse signal, and the third antenna is used to acquire the third very high frequency radiation pulse signal;
calculating, when the first baseline is orthogonal to the second baseline, calculate the azimuth angle and the elevation angle of the lightning radiation source according to the formula
$$Az = arctan ( \frac{{τ}_{d 1}}{{τ}_{d 2}} )$$
$$El = arccos ( \frac{c}{d} \sqrt{{τ}_{d 1}^{2} + {τ}_{d 2}^{2}} ) ,$$
where c is the speed of light, d is the length of baseline, τ_{d1} is the first time difference, τ_{d2} is the second time difference, Az is the azimuth angle of the lightning radiation source, and El is the elevation angle of the lightning radiation source;
calculating, when the first baseline is not orthogonal to the second baseline and the included angle between the first baseline and the due north direction is not 0, the azimuth angle and the elevation angle of the lightning radiation source according to the formula
$$Az = {Az}_{1} + arctan ( \frac{{τ}_{d 1} cos ( Δ θ ) - {τ}_{d 2}}{{τ}_{d 2} sin ( Δ θ )} )$$
$$El = arccos ( \frac{c}{d} \sqrt{\frac{{τ}_{d 1}^{2} + {τ}_{d 2}^{2} - 2 {τ}_{d 1} {τ}_{d 2} cos ( Δ θ )}{{sin}^{2} ( Δ θ )}} ) ,$$
where Δθ is the included angle between the first baseline and the second baseline, Δθ=Az₁−Az₂, Az₁ is the included angle between the first baseline and the due north direction, and Az₂ is the included angle between the second baseline and the due north direction.

9. The broadband interferometer lightning positioning system of claim 6, wherein the operations further comprise, prior to determining the pulse signal in the second very high frequency radiation pulse signal:
determining the second very high frequency radiation pulse signal within the set time period as a first main window pulse signal, and determine the third very high frequency radiation pulse signal within the set time period as a second main window pulse signal;
determining the second very high frequency radiation pulse signal in a first time period as a first auxiliary window pulse signal, determine the second very high frequency radiation pulse signal in a second time period as a second auxiliary window pulse signal, determine the third very high frequency radiation pulse signal in a first time period as a third auxiliary window pulse signal, and determine the third very high frequency radiation pulse signal in a second time period as a fourth auxiliary window pulse signal, wherein the first time period is the time period before the set time period, the second set time period is the time period after the set time period, and the first time period, the set time period and the second set time period form a continuous time period;
determining the first main window pulse signal, the first auxiliary window pulse signal, and the second auxiliary window pulse signal as the selected second very high frequency radiation pulse signal, and determine the second main window pulse signal, the third auxiliary window pulse signal, and the fourth auxiliary window pulse signal as the selected third very high frequency radiation pulse signal.

10. The broadband interferometer lightning positioning system of claim 6, wherein the operations further comprise, prior to determining the first very high frequency radiation pulse signal:
filtering the very high frequency radiation pulse signal of the lightning to obtain a filtered very high frequency radiation pulse signal.
